(19) United States
(12) Patent Application Publication
(10) Pub. No.: US 2026/0068604 A1
(43) Pub. Date: Mar. 5, 2026

(54) Method of overlay measurement for semiconductors

(71) Applicant: United Semiconductor (Xiamen) Co., Ltd., Xiamen (CN)

(72) Inventors: YAMIN GONG, Shamen City (CN); YAN CAI, Singapore (SG); WEN YI TAN, Xiamen (CN)

(73) Assignee: United Semiconductor (Xiamen) Co., Ltd., Xiamen (CN)

(21) Appl. No.: 18/902,952

(22) Filed: Oct. 1, 2024

(30) Foreign Application Priority Data
Aug. 29, 2024 (CN) 202411199767.1

(51) Int. Cl. H01L 21/66; H01L 23/544

(52) U.S. Cl. CPC H01L 22/12

(57) ABSTRACT

The invention provides a semiconductor overlay measurement method, which comprises the following steps: providing a wafer, wherein the wafer comprises a plurality of regions arranged in an array, wherein each region contains a product number pattern, and providing a system, wherein the system comprises a data pool, a plurality of English letter patterns and numeral patterns are stored in the data pool, and finding out English letter patterns and/or the numeral patterns conforming to the product number patterns from the data pool, and splicing some English letter patterns and/or some numeral patterns into an alignment mark pattern, inputting the alignment mark pattern into the system, and performing a first overlay step on the alignment mark pattern and each product number pattern on the wafer.

### BACKGROUND OF THE INVENTION

### 1. Field of the Invention

The invention relates to the field of semiconductors, in particular to an overlay measurement method for semiconductors.

### 2. Description of the Prior Art

In the semiconductor manufacturing process, overlay and alignment mark are two important technical concepts. These technologies ensure that wafers can be accurately stacked on each layer in the multi-layer structure, thus ensuring the function and performance of the circuit. With the continuous progress of process technology, the importance of these technologies has gradually increased.

Overlay refers to the relative position overlapping between different lithography layers on the wafer in the semiconductor manufacturing process. Each layer of lithography pattern must be accurately aligned with the previous layer to ensure the correct realization of circuit functions. The overlay error is a measure of this overlay deviation, usually in nanometers. In advanced process nodes (such as 7 nm and below), the requirement for overlay accuracy becomes higher, because any slight error may lead to the decline or even failure of circuit performance. Overlapping error can be divided into systematic error and random error. Systematic errors are caused by improper equipment calibration or design, which are predictable and can be reduced by correction methods, while random errors are unpredictable and caused by process or material defects, which need to be controlled by improving process stability.

Alignment mark is a reference mark used for lithography alignment in semiconductor manufacturing. These marks are usually set at specific positions on the wafer as reference points for identification and alignment of lithography equipment. Accurate fabrication and identification of alignment marks is the basis of realizing high-precision overlay. Alignment marks are usually composed of specific geometric figures, such as crosses, rings or other high-contrast figures, so as to facilitate the identification and positioning of lithography equipment. These marks need to be made in the early stage of the process, and checked and corrected during each lithography layer to ensure the alignment accuracy of all lithography layers.

In the photolithography process of semiconductor manufacturing process, alignment mark plays an important role in marking. Lithography process is a technology that uses photoresist and photomask to form patterns on the wafer surface. First, the photoresist is coated on the surface of the wafer, and then the pattern is transferred to the photoresist through the photomask by using ultraviolet light or extreme ultraviolet light. This process requires accurate overlapping to ensure that each layer of graphics can accurately overlap with the previous layer of graphics. Alignment marks provide reference points for this precise overlapping, and lithography equipment corrects the position by recognizing these marks, thus ensuring the accurate transfer of graphics.

With the continuous progress of process technology, the requirements for overlay accuracy and alignment mark are getting higher and higher. In advanced process nodes, the overlay error needs to be controlled within a few nanometers, which puts high demands on process equipment and technology. In order to meet these challenges, new overlay and calibration techniques are constantly introduced into the process technology. However, the application of this technology has also brought some new challenges, such as stricter requirements for photoresist materials and mask design.

### SUMMARY OF THE INVENTION

The invention provides a semiconductor overlay measurement method, which comprises the following steps: providing a wafer, wherein the wafer comprises a plurality of regions arranged in an array, wherein each region contains a product number pattern, and providing a system, wherein the system comprises a data pool, a plurality of English letter patterns and numeral patterns are stored in the data pool, and finding out English letter patterns and/or numeral patterns conforming to the product number patterns from the data pool. And splicing some English letter patterns and/or some numeral patterns into an alignment mark pattern, inputting the alignment mark pattern into the system, and performing a first overlay step on the alignment mark pattern and each product number pattern on the wafer.

In the prior art, when each material layer is formed, it is necessary to form an alignment mark on the material layer, then find the alignment mark of the layer, and overlay the alignment mark of the current layer with the alignment mark of the previous layer. However, the above steps repeat the steps of forming alignment marks, finding alignment marks and overlay, which prolongs the overall process time. The invention is characterized in that the product number on the surface of the wafer itself is used as the alignment mark, and the English letters or numbers contained in the product number are extracted and split, and are established in the data pool. After determining the product number of a new batch of wafers, the manufacturer can directly output the corresponding English letters and numbers from the data pool and spell them into simulated alignment marks. In this way, the step of making the alignment mark can be omitted, and because the approximate position of the product number pattern of each batch of wafers is known, the time for finding the alignment mark can also be reduced. In a word, the invention has the advantages of reducing the overlay step time and simplifying the manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic view of a wafer from above.

FIG. 2 is a schematic diagram showing a method for establishing the pattern data of the data pool of the present invention.

FIG. 3 is a schematic diagram showing the method of reading the required pattern data from the data pool and composing it into an alignment pattern.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about”or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

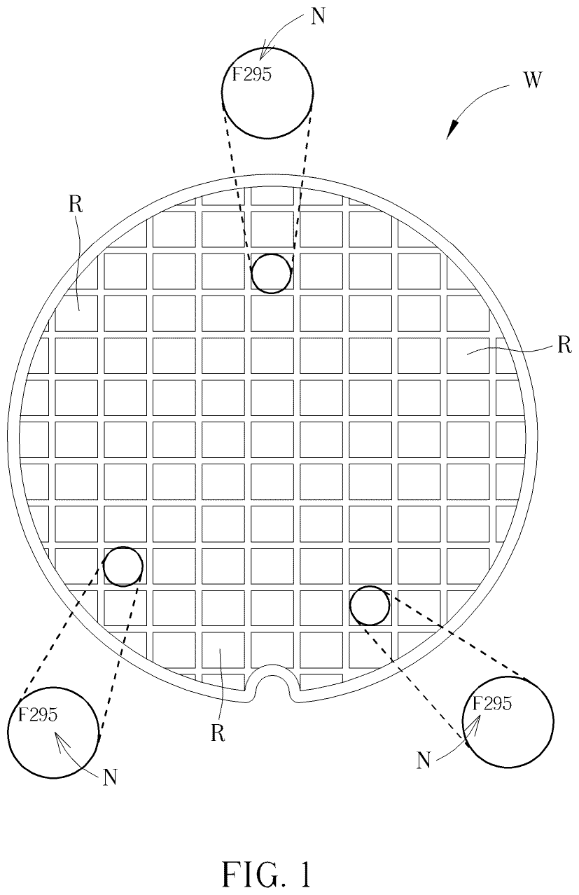

Please refer to FIG. 1, which shows a top view of a wafer. As shown in FIG. 1, a wafer W is divided into a plurality of regions R, and each region R is arranged in an array. Each region R here can be regarded as a single exposure range in the exposure process, which is known as a shot in the field. Therefore, the size of the region R on the wafer W will be adjusted with the process.

In addition, each region R contains a product number pattern N, wherein the function of the product number pattern N is to identify the products to be manufactured for the wafer or the batch of wafers. Different products will correspond to different processes, so forming the product number pattern N in each region of each wafer is helpful for the manufacturer to confirm whether the product meets the required process again during the process. Generally speaking, the product number pattern N will be located in each region R, which means that a group of product number patterns N will be included in the same position in each region R. That is, since the region R is arranged in an array, a plurality of product number patterns N are also arranged in an array, and a part of the product number patterns N is shown in FIG. 1 as an example. Taking this embodiment as an example, a product number pattern N is included in the upper left of each region R, where the product number pattern N is composed of English letters and numbers, for example, “F295” shown in FIG. 1 is an example of a product number pattern. However, it can be understood that the product number pattern N will change with the product, and the product number pattern N will not necessarily be located at the upper left of the region R. In other words, the English letters, numbers and arrangement positions included in the product number pattern N can be adjusted according to actual needs, and the invention is not limited to this.

When a wafer or a batch of wafers enters the process stage, the manufacturer will know the products corresponding to the wafer in advance, and the product number pattern N has been made in each region R on the surface of the wafer W. In other words, a wafer already contains the product number pattern N before the overlay step of multiple material layers.

In the conventional steps, in order to form the required circuit patterns, such as transistors, capacitors, wires or other electronic components, a plurality of patterned material layers are formed on the wafer and stacked with each other. In the process of stacking material layers, the steps of forming an alignment mark pattern, finding the position of the alignment mark pattern, and overlay step will be carried out for many times. In more detail, the common alignment mark pattern is, for example, a cross-shaped pattern. Therefore, when each material layer is formed, the cross-shaped alignment mark pattern can be formed in the peripheral region, and then the position of the cross-shaped pattern of the current material layer and the position of the cross-shaped pattern of the previous material layer are overlapped to confirm whether there is an offset between the two material layers. If there is an offset, positioning correction is needed. With the increasing number of material layers stacked, the time required for the above steps is gradually increasing.

The invention is characterized in that the product number pattern N formed in each region R on the wafer W is used as an alignment mark, which is used in the overlay step between the material layers. Because the product number pattern N will be formed at a fixed position in each region R (such as the upper left, but not limited to this), the step of forming the alignment mark can be omitted, and the position of the alignment mark can be quickly found. More detailed steps will be described in the following paragraphs.

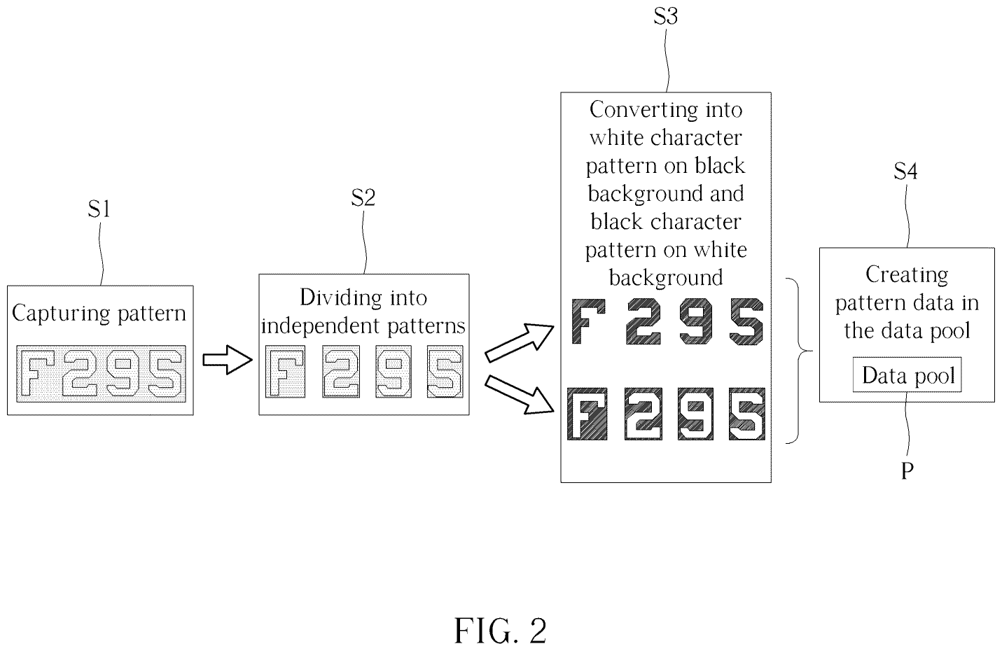

Before the overlay measurement step of the present invention, it is necessary to establish the pattern data in the data pool. Please refer to FIG. 2, which shows a schematic diagram of the method for establishing the pattern data of the data pool of the present invention. First, the manufacturer must capture the product number pattern N on the wafer W, such as the F295 pattern exemplified in the leftmost step S1 in FIG. 2 (the F295 pattern here is only an example, but the present invention is not limited to this), and then proceed to step S2 to split the F295 pattern into four independent English letters and numbers, that is, F, 2, 9 and 5. Next, in step S3, since the independent pattern at this time presents a gray scale pattern in the capture screen, it is converted into a black character pattern on white background with high contrast (for example, the upper portion of F295 pattern in step S3 in FIG. 2 is a black character pattern on white background) or a white character pattern on black background (for example, the lower portion of F295 pattern in step S3 in FIG. 2 is a white character pattern on black background). Finally, in step S4, the collected patterns are input into a data pool P to establish pattern data in the data pool P. Taking this embodiment as an example, after the F295 pattern is split and converted into a pattern with white characters on a black background or a pattern with black characters on a white background, the total of eight independent patterns are generated, and these patterns are input into the data pool P respectively. The so-called data pool P here refers to a data database in a computer system, for example. Appropriate pattern data can be stored in the data pool by the manufacturer, or the required pattern data can be captured from the data pool P.

The above steps may need to be carried out many times to complete the pattern data in the data pool P. For example, the manufacturer needs to capture patterns of multiple batches of wafers with different product number patterns N and store them in the data pool, so as to completely collect all English letters A-Z (or English letters commonly used for product number) and numbers 0-9. When there is enough pattern data in the data pool, all the required English letters and numbers can be freely spelled as required, and then the required alignment marks can be formed.

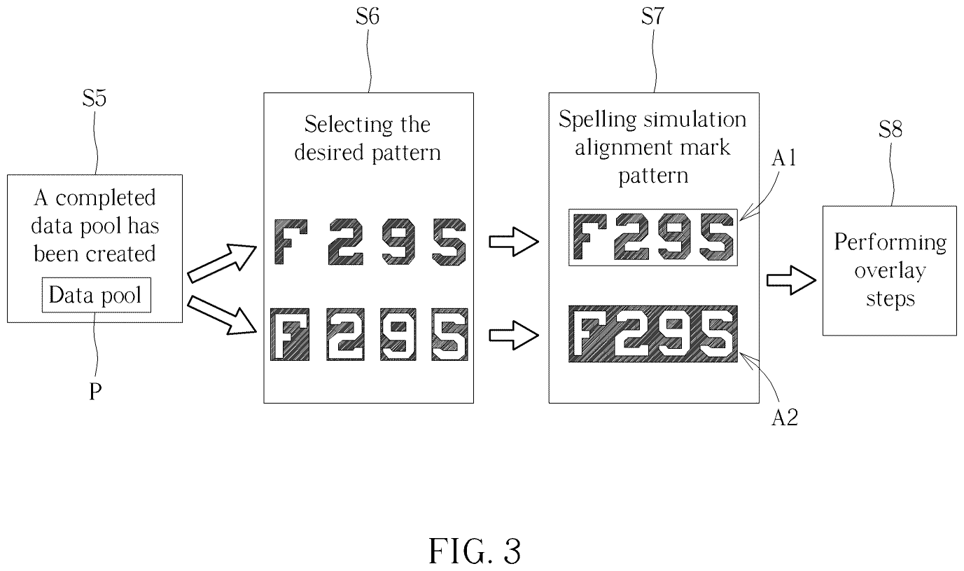

In more detail, reference can be made to FIG. 3, which shows a schematic diagram of the method of reading the required pattern data from the data pool and composing it into an alignment pattern. As shown in FIG. 3, in step S5, the collection of pattern data in the data pool P is completed, that is, as mentioned above, most English letters and numbers 0 to 9 in A to Z may be collected. Next, step S6 and step S7 are carried out. Before a batch of wafers enter the process, the manufacturer can know the product numbers of the wafers in advance, and select the corresponding English letters or numbers from the data pool P and spell them into the required string pattern. Taking this embodiment as an example, the patterns of F, 2, 9, and 5 with white characters on black background and black characters on white background can be read respectively, and they can be respectively formed into F295 patterns with white characters on black background and F295 patterns with black characters on white background. Here, the F295 pattern of black characters on white background is defined as the simulated alignment mark pattern A1, and the F295 pattern of white characters on black background is defined as the simulated alignment mark pattern A2. Next, as in step S8, the two groups of simulated alignment mark patterns A1 and A2 can be directly used as alignment marks in the overlay step, and the overlay step is performed.

More specifically, in actual operation, when each material layer is formed, the manufacturer can select a plurality of different regions R on the wafer W, and input the generated simulated alignment mark patterns A1 and A2 into the system, and also input the coordinate position of the product number pattern N into the system. Since the product number pattern N will be formed at a fixed position in each region R, the coordinate position mentioned here represents the position of the product number pattern N in the region R. After the above steps are completed, the system will automatically search for the corresponding patterns at the corresponding coordinates of the selected region R according to the input alignment mark patterns A1 and A2 (for example, the F295 pattern of white characters on a black background and the F295 pattern of black characters on a white background). If the corresponding product number pattern N can be found at the corresponding coordinates, it represents the situation when the material layer of one layer has been aligned with the material layer of the previous layer and there is no offset. On the other hand, if the system looks for the corresponding pattern at the corresponding coordinates of the selected region R and finds that the product number pattern N at the corresponding coordinates is displaced, this usually means that the material layer of the previous layer is also offset, and positioning correction can be made according to the results.

In the invention, the simulated alignment mark patterns A1 and A2 of black characters on a white background and white characters on a black background are generated respectively, which is helpful to improve the contrast of the patterns and increase the accuracy of the overlay step. In actual operation, several overlay steps can be performed with the simulated alignment mark pattern A1 of black characters on white background and the simulated alignment mark pattern A2 of white characters on black background. However, in other embodiments of the present invention, it is also possible to use only one pattern with high contrast to perform the overlay step, for example, it can use only one of the alignment mark patterns with black characters on a white background or white characters on a black background, it is also within the scope of the present invention.

Another feature of the present invention is that the product number pattern N will be formed on the surface of the wafer W at the beginning, and in order for the manufacturer to recognize the product number pattern N after forming multiple material layers, the position of the product number pattern N will not be covered by each material layer, that is, the material layer will not be covered above the product number pattern N, or after some material layers are completely covered on the substrate W, the material layer covering the product number pattern N will be removed by etching process and other steps. Therefore, the product number pattern N always existing on the surface of the wafer W can be used as the positioning point of the overlay step, and the overlay step is carried out with the product number pattern N actually existing on the surface of the wafer W by using the simulated alignment marks generated in the system (namely the simulated alignment marks A1 and A2 shown in step S7). The overlay step of the invention is suitable for each material layer, and there is no need to form a plurality of alignment marks on each material layer, so that the process steps can be saved.

In the above embodiment, “F295” is taken as an example of one of the product number patterns N, but in other embodiments of the present invention, the product number pattern N may be composed of other English letters and numbers, or only contain English letters or numbers, etc. The above variations are within the scope of the present invention.

Based on the above description and drawings, the present invention provides a semiconductor overlay measurement method, which includes providing a wafer W with a plurality of regions R arranged in an array, wherein each region R contains a product number pattern N, and providing a system including a data pool P, in which a plurality of English letter patterns and numeral patterns are stored, and finding out English letter patterns and/or numeral patterns conforming to the product number patterns from the data pool P, and splicing some English letter patterns and/or some numeral patterns into an alignment mark pattern (such as the alignment mark pattern shown in step S7), inputting the alignment mark pattern into the system, and performing a first overlay step on the alignment mark pattern and each product number pattern N on the wafer W.

In some embodiments of the present invention, the product number pattern N consists of an English letter pattern and a plurality of numeral patterns.

In some embodiments of the present invention, it further includes capturing the product number pattern N on the wafer W, and performing an identification step on the product number pattern N to identify a plurality of numeral patterns and an English letter pattern contained in the product number pattern N (as shown in step S1 of FIG. 1).

In some embodiments of the present invention, the product number pattern N is further divided into a plurality of independent numeral patterns and an independent English letter pattern (as shown in step S2 of FIG. 2).

In some embodiments of the present invention, it further includes a gray scale conversion step for each independent numeral pattern and each independent English letter pattern, so as to convert each independent numeral pattern and each independent English letter pattern into a plurality of white character patterns on a black background and into a plurality of black character patterns on a white background (as shown in step S3 of FIG. 1).

In some embodiments of the present invention, it further includes inputting a plurality of white character patterns on a black background and a plurality of black character patterns on a white background into the data pool P (as shown in step S4 of FIG. 1).

In some embodiments of the present invention, the first overlay step includes finding an English letter pattern and a plurality of numeral patterns that conform to the product number pattern from the data pool P, and arranging the English letter patterns and the plurality of numeral patterns into alignment mark patterns in sequence, wherein the English letter patterns and the plurality of numeral patterns contained in the alignment mark patterns conform to the product number patterns, inputting the alignment mark patterns and a coordinate value in the system, The system searches for the product number pattern of each region on the wafer within a range corresponding to the coordinate value of each region, and obtains an offset value (as shown in steps S5 to S8 in FIG. 3).

In some embodiments of the present invention, when the offset value is greater than a set range, a correction step is performed (that is, when the offset between the simulated alignment mark pattern and the product number pattern N on the actual wafer W is found to be too large in the overlay step, the positioning correction step is performed).

In some embodiments of the present invention, after forming a first material layer on the wafer W, a second overlay step is performed with the wafer W using the same alignment mark pattern generated by the data pool P (i.e., the simulated alignment mark patterns A1 and A2 generated in step S7) (that is, after forming another material layer, the same simulated alignment mark pattern is still overlapped with the product number pattern N on the actual wafer W).

In some embodiments of the present invention, after forming a second material layer on the first material layer, a third overlay step is performed with the wafer with the same alignment mark pattern generated by the data pool P (i.e., the simulated alignment mark patterns A1 and A2 generated in step S7) (that is, after forming another material layer, the same simulated alignment mark pattern is still overlapped with the product number pattern N on the actual wafer W).

In some embodiments of the present invention, the first overlay step, the second overlay step and the third overlay step are all performed automatically by the system.

In some embodiments of the present invention, the product number pattern N consists of a plurality of numeral patterns, but does not contain English letter patterns.

In some embodiments of the present invention, the product number pattern N consists of a plurality of English letter patterns, but does not include a numeral pattern.

In some embodiments of the present invention, each region R on the wafer W contains a product number pattern N, and a plurality of product number patterns N on the wafer W are arranged in an array.

In some embodiments of the present invention, each product number pattern N is located at the same relative position in each region R on the wafer W (for example, all in the upper left corner, but not limited to this).

In some embodiments of the present invention, each region R of the wafer W is a single shot.

In the prior art, when each material layer is formed, it is necessary to form an alignment mark on the material layer, then find the alignment mark of the layer, and overlay the alignment mark of the current layer with the alignment mark of the previous layer. However, the above steps repeat the steps of forming alignment marks, finding alignment marks and overlay, which prolongs the overall process time. The invention is characterized in that the product number on the surface of the wafer itself is used as the alignment mark, and the English letters or numbers contained in the product number are extracted and split, and are established in the data pool. After determining the product number of a new batch of wafers, the manufacturer can directly output the corresponding English letters and numbers from the data pool and spell them into simulated alignment marks. In this way, the step of making the alignment mark can be omitted, and because the approximate position of the product number pattern of each batch of wafers is known, the time for finding the alignment mark can also be reduced. In a word, the invention has the advantages of reducing the overlay step time and simplifying the manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An overlay measurement method for semiconductors, characterized in that:
providing a wafer, which comprises a plurality of regions arranged in an array, wherein each region contains a product number pattern;
providing a system, which comprises a data pool, wherein a plurality of English letter patterns and numeral patterns are stored in the data pool, finding the English letter patterns and/or the numeral patterns conforming to the product number patterns from the data pool, and splicing the English letter patterns and/or the numeral patterns into an alignment mark pattern; and
inputting the alignment mark pattern into the system, and performing a first overlay step on the alignment mark pattern and each product number pattern on the wafer.

2. The overlay measurement method according to claim 1, wherein the product number pattern is composed of an English letter pattern and a plurality of numeral patterns.

3. The overlay measurement method of semiconductor according to claim 1, further comprising:
capturing the product number pattern on the wafer, and performing an identification step on the product number pattern to identify a plurality of numeral patterns and an English letter pattern contained in the product number pattern.

4. The overlay measurement method of semiconductor according to claim 3, further comprising splitting the product number pattern into a plurality of independent numeral patterns and an independent English letter pattern.

5. The semiconductor overlay measurement method according to claim 4, further comprising performing a gray scale conversion step for each independent numeral pattern and the independent English letter pattern, so as to convert each independent numeral pattern and the independent English letter pattern into a plurality of white character patterns on a black background and into a plurality of black character patterns on a white background.

6. The overlay measurement method according to claim 5, further comprising inputting the plurality of white character patterns on a black background and the plurality of black character patterns on a white background into the data pool.

7. The overlay measurement method according to claim 6, wherein the first overlay step comprises:
searching for an English letter pattern and a plurality of numeral patterns which conform to the product number pattern from the data pool, and arranging the English letter pattern and the plurality of numeral patterns into the alignment mark pattern in sequence, wherein the English letter pattern and the plurality of numeral patterns contained in the alignment mark pattern conform to the product number pattern;
inputting the alignment mark pattern and a coordinate value in the system;
the system searches for the product number pattern of each region on the wafer within a range corresponding to the coordinate value of each region, and obtains an offset value.

8. The overlay measurement method of semiconductor according to claim 7, further comprising:
performing a correction step when the offset value is greater than a set range.

9. The overlay measurement method of semiconductor according to claim 1, further comprising:
performing a second overlay step with the wafer using the same alignment mark pattern generated by the data pool after a first material layer is formed on the wafer.

10. The overlay measurement method of semiconductor according to claim 9, further comprising:
performing a third overlay step with the wafer using the same alignment mark pattern generated by the data pool after a second material layer is formed on the wafer.

11. The overlay measurement method according to claim 10, wherein the first overlay step, the second overlay step and the third overlay step are all automatically performed by the system.

12. The overlay measurement method of semiconductor according to claim 1, wherein the product number pattern is composed of a plurality of numeral patterns, but does not include English letter patterns.

13. The overlay measurement method of semiconductor according to claim 1, wherein the product number pattern is composed of a plurality of English letter patterns, but does not include numeral patterns.

14. The overlay measurement method according to claim 1, wherein each region on the wafer contains one product number pattern, and the plurality of product number patterns on the wafer are arranged in an array.

15. The overlay measurement method according to claim 14, wherein each of the product number patterns is located at the same relative position in each of the regions on the wafer.

16. The overlay measurement method according to claim 1, wherein each region of the wafer is a single exposure shot.
